(19) United States
(12) Patent Application Publication
(10) Pub. No.: US 2013/0258129 A1
(43) Pub. Date: Oct. 3, 2013

(54) METHOD AND APPARATUS FOR MANAGING ORIENTATION IN DEVICES WITH MULTIPLE IMAGING SENSORS

(71) Applicant: David William Burns, San Jose, CA (US)

(72) Inventor: David William Burns, San Jose, CA (US)

(73) Assignee: QUALCOMM Incorporated, San Diego, CA (US)

(21) Appl. No.: 13/544,726

(22) Filed: Jul. 9, 2012

Related U.S. Application Data
(60) Provisional application No. 61/616,930, filed on Mar. 28, 2012.

(51) Int. Cl. H04N 5/225; H01L 27/146

(52) U.S. Cl. 348/222.1; 250/208.1

(57) ABSTRACT

Described herein are methods and devices that capture a stereoscopic image with a device that has a first pair of imaging sensors and a second pair of imaging sensors. When a stereoscopic image is to be taken, the orientation of the device is detected and the appropriate pair of imaging sensors is selected based on the detected device orientation. A stereoscopic image pair may then be captured with the selected pair of imaging sensors.

### CROSS-REFERENCE TO RELATED APPLICATIONS

The disclosure claims priority to U.S. Provisional Patent Application No. 61/616,930 filed Mar. 28, 2012, entitled “METHOD AND APPARATUS FOR MANAGING ORIENTATION IN MULTI-IMAGING SENSOR DEVICES ORIENTATIONS,” and assigned to the assignee hereof. The disclosure of this prior application is considered part of, and is incorporated by reference in, this disclosure.

### TECHNICAL FIELD

The present embodiments relate to imaging devices, and in particular, to imaging devices that include multiple imaging sensors.

### BACKGROUND

Digital imaging capabilities are being integrated into a wide range of devices, including digital cameras and mobile phones. Advances in the ability to manufacture accelerometers and orientation sensors in smaller form factors and at a reduced cost have also led to the integration of these devices into digital imaging devices. Today, many digital imaging devices include orientation sensors such as accelerometers, inclinometers, rotation sensors, and magnetometers. With suitable image processing, imaging sensors themselves may be used as orientation sensors. Photos or movies can be captured when the digital imaging device is held in either a portrait or a landscape orientation. A digital image format may provide data fields for the orientation data. For example, the Exif standard defines a field to store some orientation information. Some imaging devices take advantage of this capability and store an indication of the orientation of the digital imaging device at the time a photo or movie is captured along with the digital image data itself. When the photo is later viewed, the photo can be displayed in its proper orientation based on the orientation data stored with the image data.

Recently, multiple imaging sensors are being integrated into a wide range of electronic devices. These include mobile wireless communication devices, personal digital assistants (PDAs), personal music systems, digital cameras, digital recording devices, video conferencing systems, and the like. A wide variety of capabilities and features can be enabled with multiple imaging sensors. These include stereoscopic (3-D) imaging applications such as 3-D photos and videos or movies, and also higher dynamic range imaging and panoramic imaging.

In some cases, the multiple imaging sensors for 3-D imaging are aligned along a horizontal axis when the imaging device is held in a particular orientation. There may be a distance or offset between the two imaging sensors in this orientation. When a user holds the device in this orientation and captures a pair of images with the two imaging sensors, electronic processing methods within the camera may process the image pair based on the horizontal offset present between the imaging sensors that captured the image pair. For example, stereoscopic imaging applications may rely on a horizontal offset between two imaging sensors to create the parallax necessary for the creation of a three-dimensional effect.

If the orientation of the imaging device is varied, the horizontal offset between the two imaging sensors may also vary. For example, two imaging sensors may be offset horizontally by a first distance when the digital imaging device is held in a landscape orientation. There may be no vertical offset between the two imaging sensors in the landscape orientation. When the device is held in a portrait orientation, the horizontal offset between the two imaging sensors may become a vertical offset. In the portrait orientation, there may be no horizontal offset between the two imaging sensors. Similarly, if two imaging sensors have no vertical offset when the device is held in the portrait orientation, they will have no horizontal offset when held in the landscape orientation. The imaging sensors may have a vertical offset in the landscape orientation. With such a device, images captured by the two imaging sensors while the device is in the portrait orientation may not provide the horizontal parallax necessary for satisfactory stereoscopic image pairs.

### SUMMARY

Some of the present embodiments may include a method of capturing a stereoscopic image from a device having a first pair of imaging sensors and a second pair of imaging sensors. First, a device orientation may be detected. Either the first pair or the second pair of imaging sensors is selected based on the detected device orientation. A stereoscopic image pair may then be captured using the selected pair of imaging sensors. The stereoscopic image pair may then be sent to a data store.

One innovative aspect disclosed is a stereoscopic imaging apparatus. The apparatus includes a first pair of imaging sensors aligned along a first axis with respect to the apparatus, and a second pair of imaging sensors aligned along a second axis with respect to the apparatus. The second axis is substantially perpendicular to the first axis. The apparatus also includes a control module configured to capture stereoscopic images from the first pair of imaging sensors when the apparatus is in a first orientation and the second pair of imaging sensors when the apparatus is in a second orientation. In some implementations, the first pair of imaging sensors and the second pair of imaging sensors share a common imaging sensor. In some implementations, the apparatus also includes an orientation sensor. In these implementations, the control module selects the first pair or the second pair of imaging sensors based at least in part on an output from the orientation sensor. In some implementations, the apparatus is a wireless telephone handset.

Another innovative aspect is a method for capturing a stereoscopic image from a device having a first pair of imaging sensors and a second pair of imaging sensors. The method includes detecting a device orientation, selecting the first pair or the second pair of imaging sensors based on the device orientation, capturing a stereoscopic image pair with the selected pair of imaging sensors, and sending the stereoscopic image pair to a data store. In some implementations, the device orientation is detected by obtaining data from an orientation sensor associated with the device. In some implementations, the first pair of imaging sensors and the second pair of imaging sensors share one imaging sensor. In some implementations, the first pair of imaging sensors and the second pair of imaging sensors do not share an imaging sensor. In some implementations, the device is a wireless telephone handset.

Another innovative aspect disclosed is a stereoscopic imaging apparatus. The apparatus includes means for detecting a device orientation, means for selecting a first pair of imaging sensors or a second pair of imaging sensors based on the device orientation, means for capturing a stereoscopic image pair with the selected pair of imaging sensors, and means for sending the stereoscopic image pair to a data store. In some implementations, the means for detecting a device orientation includes an orientation sensor. In some implementations, the means for capturing a stereoscopic image pair includes processor instructions in a sensor control module.

In some implementations, the means for selecting the first pair or the second pair of imaging sensors based on the device orientation includes processor instructions in a sensor selection module.

Another innovative aspect disclosed includes a non-transitory computer-readable medium comprising instructions that when executed by a processor perform a method of detecting a device orientation, selecting a first pair of imaging sensors or a second pair of imaging sensors based on the device orientation, capturing a stereoscopic image pair with the selected pair of imaging sensors, and sending the stereoscopic image pair to a data store. In some implementations, the device orientation is detected by obtaining data from an orientation sensor coupled to the device.

Another innovative aspect disclosed is a method for correcting level distortion in a digital image captured by a digital imaging device having a body and an imaging sensor. The method includes measuring a tilt angle between the imaging sensor and a horizontal surface, adjusting the tilt angle by changing electronically or mechanically the position of the imaging sensor within the body of the digital imaging device, capturing an image with the imaging sensor, and sending the image to a data store. In some implementations, measuring the tilt angle includes obtaining tilt data from an orientation sensor coupled to the digital imaging device. In some implementations, measuring the angle between the imaging sensor and the horizontal surface comprises measuring the angle between a lens of the imaging sensor and the horizontal surface.

In some implementations, the method also includes adjusting a tilt angle that a second imaging sensor makes with the horizontal surface by changing a position of the second imaging sensor. In these implementations, the second imaging sensor is within the body of the digital imaging device. In some implementations, the method is performed in a wireless telephone handset.

Another innovative aspect disclosed is a digital imaging device. The digital imaging device includes an imaging sensor, an orientation sensor, and a processor, the processor operatively coupled to the imaging sensor and the orientation sensor. The device also includes an orientation module, the orientation module configured to read data from the orientation sensor and determine a tilt angle between the imaging sensor and a horizontal surface, and an orientation control module configured to adjust the tilt angle by changing electronically or mechanically a position of the imaging sensor within the digital imaging device.

Some implementations include an image capture module configured to capture an image with the imaging sensor, and a master control module configured to send the image to a data store. In some implementations, the device also includes an integrated data store. In these implementations, a master control module is configured to send the image to the integrated data store. In some implementations, the data store is accessible over a network. Some implementations of the digital imaging device also include a second imaging sensor. In these implementations, the orientation control module is further configured to adjust a tilt angle of the second imaging sensor by changing a position of the second imaging sensor within the body of the digital imaging device. In some implementations, the image capture module is further configured to capture a second image with the second imaging sensor.

Another innovative aspect is a digital imaging device including a body and an imaging sensor. The digital imaging device includes means for measuring a tilt angle between the imaging sensor and a horizontal surface, means for adjusting the tilt angle by changing electronically or mechanically the position of the imaging sensor within the body of the digital imaging device, means for capturing an image with the imaging sensor, and means for sending the image to a data store. In some implementations, the device includes means for capturing an image with a second imaging sensor. In some implementations, the device also includes means for adjusting a tilt angle of the second imaging sensor with respect to the horizontal surface by changing electronically or mechanically the position of the second imaging sensor. In some other implementations, the data store is integrated with the digital imaging device.

Another innovative aspect disclosed is a non-transitory computer readable medium, storing instructions that when executed by a processor cause the processor to perform the method of measuring a tilt angle between an imaging sensor and a horizontal surface, adjusting the tilt angle by changing electronically or mechanically the position of an imaging sensor within a body of a digital imaging device, capturing an image with the imaging sensor; and sending the image to a data store.

### BRIEF DESCRIPTION OF THE DRAWINGS

The disclosed aspects will hereinafter be described in conjunction with the appended drawings, provided to illustrate and not to limit the disclosed aspects, wherein like designations denote like elements.

FIG. 1 shows one implementation of an apparatus that includes a first pair of imaging sensors aligned along a first axis and a second pair of imaging sensors aligned along a second axis of the apparatus.

FIG. 2 shows one implementation of an apparatus that includes a first pair of imaging sensors aligned along a first axis and a second pair of imaging sensors aligned along a second axis of the apparatus.

FIG. 3 is a block diagram of an imaging device including three imaging sensors.

FIG. 4 is a flowchart of a process for selecting a pair of imaging sensors based on a device orientation.

FIG. 5 is a flowchart of a process for capturing a stereoscopic image pair using a pair of selected imaging sensors.

FIG. 6 shows a flowchart of a process for capturing a stereoscopic image pair based on a device orientation.

FIG. 7A illustrates an imaging device positioned at an angle or tilt relative to a scene being imaged.

FIG. 7B illustrates an imaging device including an imaging sensor with an adjustable level control.

FIG. 7C illustrates an imaging device with an opposite tilt as compared to FIG. 7B.

FIG. 8 is a block diagram of an imaging device implementing at least one of the methods and apparatus disclosed herein.

FIG. 9 is a flowchart of a process for detecting and compensating for the orientation or tilt of an imaging device before capturing one or more images.

FIG. 10 shows an imaging device implementing at least one of the apparatus and methods disclosed herein.

FIG. 11 is a block diagram of an imaging device implementing at least one of the methods and apparatus disclosed herein.

FIG. 12 shows a flowchart of a process for electronically adjusting a digital image to remove level distortion.

### DETAILED DESCRIPTION

The following detailed description is directed to certain implementations for the purposes of describing the innovative aspects. However, the teachings herein can be applied in a multitude of different ways. The described implementations may be implemented in any device that is configured to capture an image, whether a two dimensional image, three dimensional image, or stereoscopic image. Images may be captured of scenes in motion (e.g., video) or stationary (e.g., still images). More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, television monitors, flat panel displays, computer monitors, camera view displays (e.g., display of a rear view camera in a vehicle.) Thus, the teachings are not intended to be limited to the implementations depicted solely in the Figures, but instead have wide applicability as will be readily apparent to a person having ordinary skill in the art.

One implementation relates to an apparatus or method for capturing a stereoscopic image when a digital capture device is used in one of multiple orientations. In one embodiment, the apparatus includes three imaging sensors configured in pairs that are substantially at right angles to one another, with one imaging sensor in common with each pair. In another embodiment, the apparatus includes two separate pairs of imaging sensors. The apparatus may include a processing module that selects two of the three sensors to capture the stereoscopic image. The apparatus may be configured to select the pair of imaging sensors that results in a stereoscopic image corresponding to a particular orientation of the digital device. The disclosed methods may operate continuously and transparently during normal use of the device. The methods and apparatus may be applied to still or video stereographic imaging. These methods and apparatus may reduce or eliminate the need for a user to manually select a pair of imaging sensors to use for an imaging task. These methods and apparatus may allow a user to capture three-dimensional images in either landscape or portrait mode with a digital capture device. These methods and apparatus may also provide improved flexibility in device orientation when utilizing imaging applications that rely on multiple imaging sensors. One skilled in the art will recognize that these embodiments may be implemented in hardware, software, firmware, or any combination thereof.

Embodiments of the apparatus or device described herein can include at least three imaging sensors. A first pair of imaging sensors may be aligned along a first axis. A second pair of imaging sensors may be aligned along a second axis, with the second axis being positioned orthogonal to the first axis. In some implementations, the first pair of imaging sensors may not include any imaging sensors that are also included in the second pair of imaging sensors. Some implementations may include at least four imaging sensors. In other implementations, the first and second pair of imaging sensors may share an imaging sensor. These implementations may include at few as three imaging sensors.

In the disclosed methods and apparatus, the two pairs of imaging sensors can each be aligned along an axis. The two axes may be positioned with an approximately 90° angle between them. In other words, the two axes are perpendicular or orthogonal to each other. This configuration may allow one pair of imaging sensors to be aligned horizontally when the device is in a portrait orientation, and the other pair of imaging sensors to be aligned horizontally when the device is in a landscape orientation. Similarly, one pair of imaging sensors may be aligned along a vertical axis when the device is in a portrait orientation, and a second pair of imaging sensors may be aligned vertically when the device is in a landscape orientation. Therefore, using the disclosed apparatus and methods, applications that depend upon a particular respective orientation between two imaging sensors may be less restricted in the device orientations in which they may operate, when compared to known devices.

In the following description, specific details are given to provide a thorough understanding of the examples. However, it will be understood by one of ordinary skill in the art that the examples may be practiced without these specific details. For example, electrical components/devices may be shown in block diagrams in order not to obscure the examples in unnecessary detail. In other instances, such components, other structures and techniques may be shown in detail to further explain the examples.

It is also noted that the examples may be described as a process, which is depicted as a flowchart, a flow diagram, a finite state diagram, a structure diagram, or a block diagram. Although a flowchart may describe the operations as a sequential process, many of the operations can be performed in parallel, or concurrently, and the process can be repeated. In addition, the order of the operations may be re-arranged. A process may be terminated when its operations are completed. A process may correspond to a method, a function, a procedure, a subroutine, a subprogram, etc. When a process corresponds to a software function, its termination may correspond to a return of the function to the calling function or the main function.

Those of skill in the art will understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

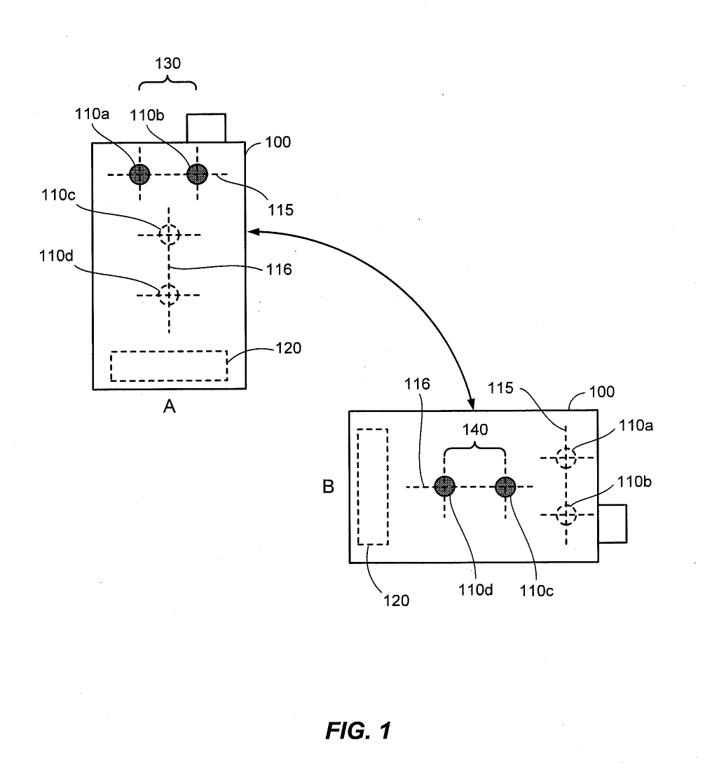

FIG. 1 shows one implementation of a digital imaging device 100 that includes a first pair of imaging sensors 110a and 110b aligned along a first axis 115 and a second pair of imaging sensors 110c and 110d aligned along a second axis 116. The device 100 is shown in two orientations, a first vertical orientation A and a second horizontal orientation B. The device 100 includes four imaging sensors, identified as 110a-d. The device also includes an orientation sensor 120 such as one or more accelerometers, inclinometers, rotation sensors, and magnetometers. With suitable image processing of visible features, imaging sensors themselves may be used as orientation sensors. In the vertical orientation A, imaging sensors 110a and 110b are shown in a shaded or selected state. In some implementations, some imaging applications may select the imaging sensors 110a and 110b for image capture operations when the device is in the vertical orientation A. The shaded imaging sensors 110a and 110b may be selected based, at least in part, on input from the orientation sensor 120. A stereoscopic imaging application may use the horizontal offset 130 present between imaging sensor 110a and 110b to create parallax in stereoscopic image pairs captured by device 100 in the vertical orientation.

Other imaging applications may select imaging sensors 110c and 110d for image capture operations when the device is in vertical orientation A. For example, a user lying on his/her side may choose imaging sensors 110c and 110d when the device is in the vertical orientation A. Other imaging applications may use only one imaging sensor when the device is in this orientation. For example, imaging sensor 110c may be used by some applications. In some configurations, each of the imaging sensors 110a and 110b may be wider along the axis 115 to match a desired video aspect ratio format such as 4:3 or 16:9. Imaging sensors 110c and 110d may be wider along axis 116 to match the desired aspect ratio. In other configurations, imaging sensors 110a and 110b may be narrower along axis 115 to allow 3-D still or video images to be captured in a portrait view, while imaging sensors 110c and 110d remain wider along axis 116 for image capture in a landscape view. In yet other configurations, imaging sensors 110a-d may have a square imaging pixel format, from which a subset of pixels may be selected to obtain the desired aspect ratio (e.g. in either landscape or portrait view with either pair of imaging sensors).

The device 100 may also be positioned in the horizontal or landscape orientation B. In some implementations, some imaging applications may select the shaded imaging sensors 110c and 110d for image capture operations when the device is in orientation B. Similar to the offset 130 between imaging sensors 110a and 110b when the device is in the vertical orientation A, some imaging applications may rely on the horizontal offset 140 between imaging sensors 110c and 110d when the device is in horizontal orientation B to obtain 3-D imagery. Some implementations of device 100 may be designed such that the horizontal offset 130 is equivalent to the horizontal offset 140. Other implementations may provide for horizontal offset 130 to be different from horizontal offset 140. In some implementations, stereoscopic processing methods are stored in the device 100 and may compensate for differences in the offset distance 130, which may be present in images captured when the device is in a vertical orientation A, and to compensate for differences in offset distance 140, which may be present when images are captured with the device in orientation B.

Note that while device 100 is shown with four imaging sensors in FIG. 1, this implementation is not limited to four imaging sensors. For example, device 100 may include 5, 6, 7, 8 or more imaging sensors, such as dual pairs of imaging sensors on the display side and on the back side of a mobile phone or a tablet computer. Note also that imaging device 100 may be implemented as a dedicated digital camera, or may be integrated with other devices. For example, device 100 may be a wireless telephone handset.

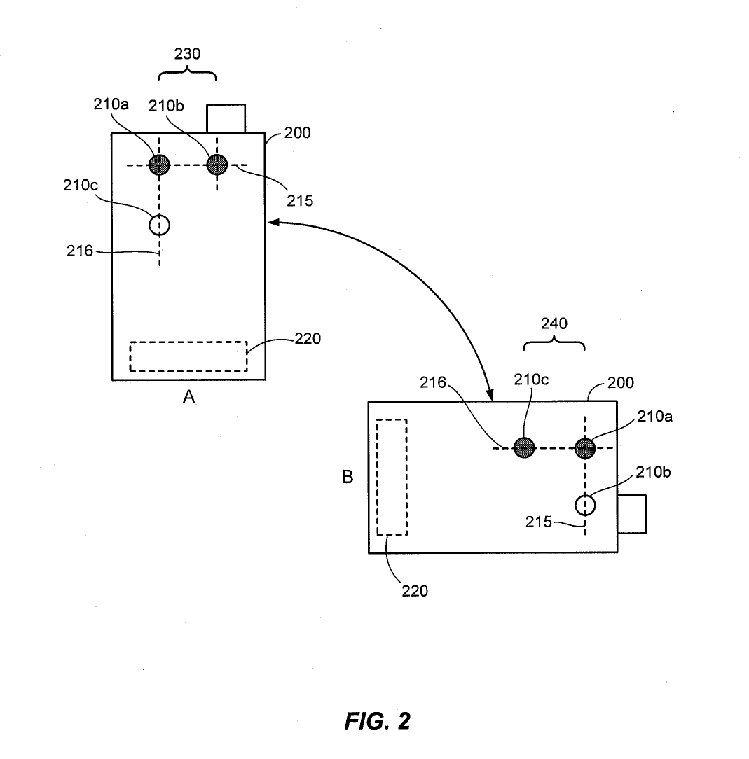

FIG. 2 shows one implementation of an apparatus 200 that includes a first pair of imaging sensors 210a and 210b aligned along a first axis 215 and a second pair of imaging sensors 210a and 210c aligned along a second axis 216 of the apparatus 200. The device 200 shown in FIG. 2 may differ from the device 100 of FIG. 1 in that it may include only three imaging sensors. The first pair of imaging sensors and the second pair of imaging sensors may share a common imaging sensor. FIG. 2 shows device 200 illustrated in a vertical or portrait orientation A and in a horizontal or landscape orientation B. The imaging sensors 210a and 210b of device 200 are shown in each of the selected orientations. These imaging sensors may be selected by an imaging application for image capture operations when the device 200 is in the vertical orientation A, as shown. Imaging sensors 210a and 210c are shown selected when device 200 is in orientation B. Some applications may select imaging sensors 210a and 210c for image capture operations when the device is in the landscape orientation B. As in FIG. 1, stereoscopic applications may rely on a horizontal offset distance 230 to create parallax in images captured with this device orientation. The offset 230 between imaging sensors 210a and 210b may be equivalent to the offset 240 between imaging sensors 210a and 210c. Alternatively, offset 230 may be different than offset 240. When offset 230 and offset 240 are different, electronic processing methods in device 200 may adjust stereoscopic image pairs captured by device 200 to compensate for the differing offsets.

In some implementations, the dual-pair of stereographic imaging sensors 110a-d of FIG. 1 or the L-shaped arrangement of imaging sensors 210a-c of FIG. 2 may be configured at various positions on a mobile or hand-held device, such as at or near the center of the device, or at or near a side or a corner of the device. In some configurations, the imaging sensors may be positioned near the center of one or more sides or corners, peripheral to a display (not shown) on the mobile device. In some configurations, the stereographic imaging sensors may be mounted on the backside of a mobile device, opposite a display side. In some configurations, the imaging sensors may be mounted on an edge or side of the mobile device. In some configurations, the stereographic imaging sensors may be mounted on the front (display) side of a mobile device and another set on the backside of the device. A control module in the mobile device may determine which set of imaging arrays are used to capture stereographic images.

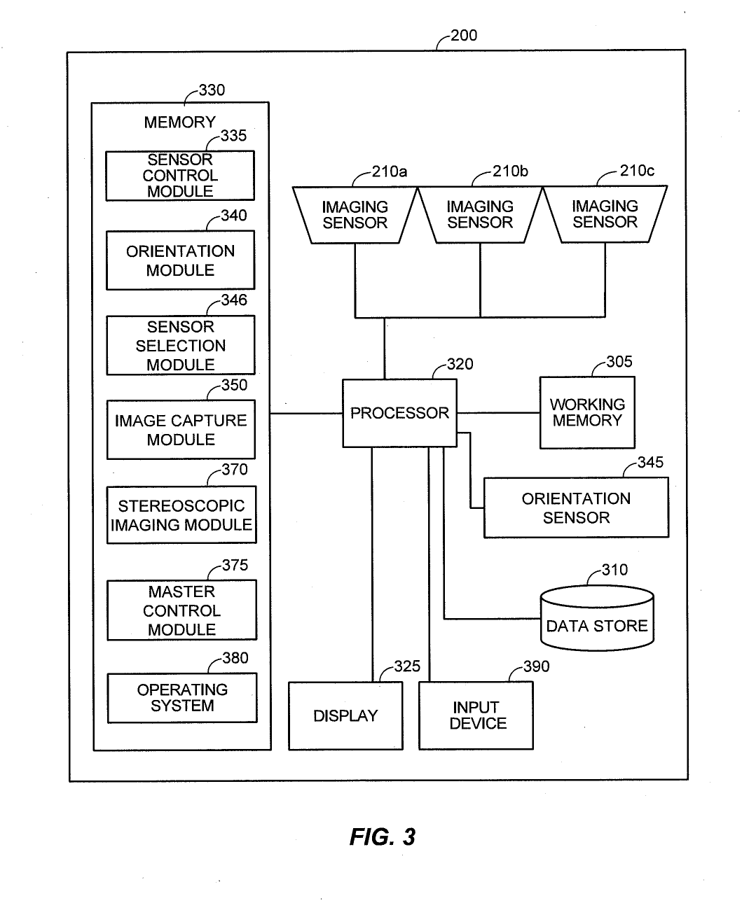

FIG. 3 is a block diagram of an imaging device including three imaging sensors. The imaging device 200 includes a processor 320 operatively coupled to several components, including a memory 330, a first imaging sensor 210a, a second imaging sensor 210b, and a third imaging sensor 210c. Some implementations of the device 200 may have more imaging sensors, for example, a fourth imaging sensor (not shown). Also operatively coupled to the processor 320 are a working memory 305, a data store 310, a display 325, an orientation sensor 345, and an input device 390. Note that although device 200 is illustrated as including a data store 310, other implementations of device 200 may access a data store over a network such as a remote data store. In those implementations, a network interface may be included with device 200. In those implementations, a data storage, such as data store 310, may or may not be included in the device 200.

The imaging device 200 may receive input via the input device 390. For example, input device 390 may be comprised of one or more keys included in imaging device 200. These keys may control a user interface displayed on the electronic display 325. Alternatively, these keys may have dedicated functions that are not related to a user interface. For example, the input device 390 may include a shutter release key. The imaging device 200 may send captured images to and store captured images in data store 310. These images may include traditional (non-stereoscopic) digital images or movies, or stereoscopic image pairs including stills or video captured by one or more of the imaging sensors 210a, 210b, and 210c. The working memory 305 may be used by the processor 320 to store dynamic run time data created during normal operation of the imaging device 200.

The memory 330 may be configured to store one or more software or firmware code modules. These modules contain instructions that configure the processor 320 to perform certain functions as described below. For example, an operating system module 380 may include instructions that configure the processor 320 to manage the hardware and software resources of the device 200. A sensor control module 335 may include instructions that configure the processor 320 to control the imaging sensors 210a-c. For example, some instructions in the sensor control module 335 may configure the processor 320 to capture an image with one of the imaging sensors 210a-c. Alternatively, instructions in the sensor control module 335 may configure the processor 320 to capture two images using two of imaging sensors 210a-c. These two images may comprise a stereoscopic image pair. Therefore, instructions in the sensor control module 335 may represent one means for capturing an image with an imaging sensor. These instructions may also represent one means for capturing a stereoscopic image pair with a pair of imaging sensors.

Orientation module 340 may include instructions that configure the processor 320 to read or obtain data from the orientation sensor 345. This data may indicate the current orientation of device 200. For example, if device 200 is being held in a vertical or portrait orientation, as illustrated by orientation A of FIG. 2, data read from the orientation sensor 345 by instructions included in the orientation module 340 may indicate the vertical or portrait position. Similarly, if device 200 is held in a horizontal or landscape orientation B as illustrated in FIG. 2, the data read from the accelerometer or orientation sensor 345 may indicate a horizontal or landscape position.

The orientation module 340 may track the orientation of device 200 using several designs. For example, the orientation module may “poll” the orientation sensor 345 at a regular time or poll period. At each poll interval, instructions in the orientation module 340 may read orientation data from the orientation sensor 345 and record the information in data store 310 or working memory 305. Orientation module 340 may include instructions that implement methods to “debounce” or buffer the data from orientation sensor 345. For example, a method of determining a device orientation may include counting the number of sequential data points received from an orientation sensor that indicate a consistent orientation. Before these methods indicate a change in orientation, the number of sequential data points that indicate a new orientation may need to exceed a threshold. These methods may prevent spurious data points of device orientation while the device 200 is being moved, for example.

Another design of the orientation module may utilize interrupts from the orientation sensor 345. For example, the orientation sensor 345 may be designed to provide an interrupt signal when the device 200 changes orientation. When this interrupt signal occurs, the processor 320 may be configured to execute instructions inside the orientation module 340. These instructions may save orientation data read or obtained from the orientation sensor 345 in response to the interrupt. In some implementations, the orientation sensor 345 may provide the debouncing or buffering described above and only interrupt device 200 when the device has stabilized in a new orientation. Alternatively, the orientation sensor 345 may interrupt processor 320 at any change in orientation, and instructions in the orientation module 340 may provide a buffering or debouncing capability as described above in the polling implementation.

A sensor selection module 346 includes instructions that configure the processor 320 to select the preferred pair of imaging sensors based on the orientation of device 200. For example, instructions in the sensor selection module 346 may read orientation data from the orientation module 340 and select a pair of imaging sensors based on the data. For example, the sensor selection module 346 may select imaging sensors 210a and 210b when the device 200 is in a first orientation. Alternatively, when the device 200 is in a second orientation, instructions in the sensor selection module 346 may select the imaging sensors 210b and 210c. Alternatively, in a non-stereographic mode, the sensor selection module 346 may select one of imaging sensors 210a-c when the device 200 is in a first orientation, and select another imaging sensor 210a-c when in a second orientation to allow image acquisition in a desired aspect ratio in either a landscape or a portrait mode.

An image capture module 350 may include instructions to capture traditional single-image photos. For example, instructions in the image capture module 350 may call subroutines in the sensor control module 335 to capture an image with one of imaging sensors 210a-c. The image capture module 350 may choose a sensor to capture an image based on the imaging sensors selected by sensor selection module 346. Additional instructions in image capture module 350 may then configure the processor 320 to send and store the captured image data in the data store 310. Image capture module 350 may also receive input from the input device 390. For example, when device 200 is in an image capture mode, a shutter release input from the input device 390 may trigger instructions in the image capture module 350 to capture one or more images.

A stereoscopic imaging module 370 may include instructions to capture stereoscopic images with two of the imaging sensors 210a-c. In some implementations, the stereoscopic imaging module 370 may capture a stereoscopic image using imaging sensors selected by instructions in the sensor selection module 346. This implementation “encapsulates” the details of managing which imaging sensors are selected based on the orientation of the device 200 in one module, such as sensor selection module 346. This architecture may simplify the design of other modules, such as the image capture module 350 or the stereoscopic imaging module 370. With this architecture, these modules may not need to manage which imaging sensors are selected based on the orientation of device 200.

In some implementations, the stereoscopic imaging module 370 may also read or obtain data from the orientation sensor 345 via the orientation module 340 to determine which imaging sensors should be used to capture a stereoscopic image pair. For example, if data from the orientation sensor 345 indicates the device 200 is in a portrait orientation, the stereoscopic imaging module 370 may capture a stereoscopic image pair using imaging sensors 210a and 210b. If data read from the orientation sensor 345 indicates that device 200 is in a horizontal or landscape orientation, stereoscopic imaging module 370 may capture a stereoscopic image pair using imaging sensors 210b and 210c.

A master control module 375 includes instructions to control the overall functions of imaging device 200. For example, instructions in the master control module 375 may call subroutines in the image capture module 350 when the device 200 is placed in a photo or video mode. Master control module may also call subroutines in stereoscopic imaging module 370 when the device 200 is placed in a stereoscopic photo or video imaging mode.

A fourth imaging sensor (not shown) may be included with the imaging device 200 for implementations that include a first pair of imaging sensors aligned along a first axis and a second pair of imaging sensors aligned along a second axis, where the imaging sensors are not in common. The master control module may capture images using the first pair of imaging sensors when the device 200 is in a first orientation. The master control module 375 may capture images using the second pair of imaging sensors when the device 200 is in a second orientation.

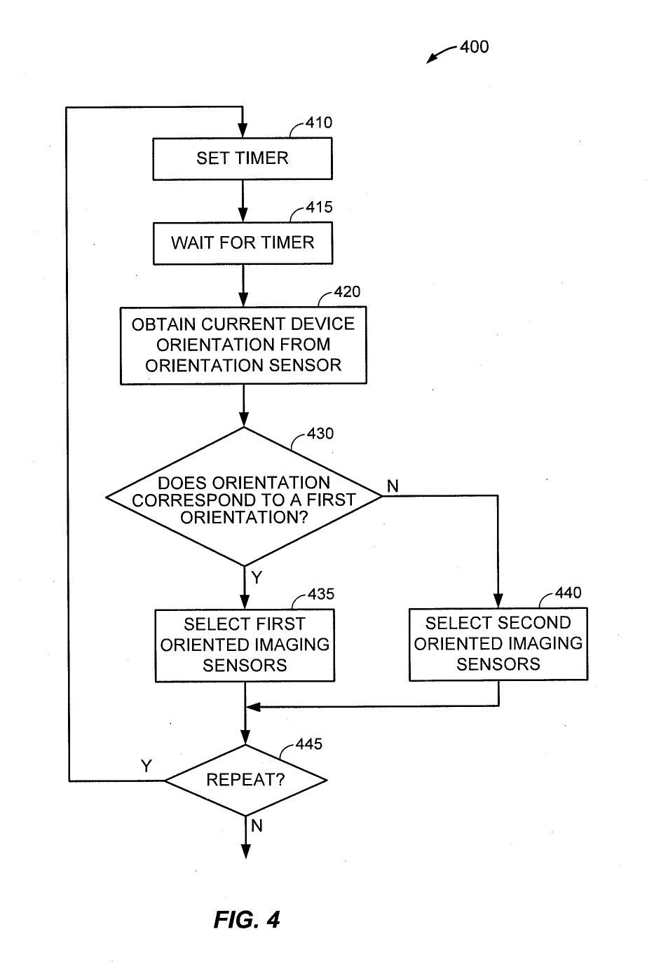

FIG. 4 is a flowchart of a process for selecting a pair of imaging sensors based on a device orientation. The process 400 may be implemented, for example, by instructions included in the orientation module 340, stereoscopic imaging module 370, or master control module 375, as illustrated in FIG. 3. In block 410 a timer is set. For example, operating system module 380 may include instructions that provide a timer capability. Instructions in the orientation module 340 may invoke subroutines in the operating system module 380 to set a timer. The process 400 may then move to block 415 where the process 400 waits for the timer to expire. For example, the operating system module 380 may include instructions that implement a “sleep on event” capability. To wait for a timer to expire, the orientation module 340 may invoke a “sleep on event” subroutine in the operating system module 380. A parameter passed to the “sleep on event” subroutine may include an identifier for the timer set in processing block 410. When the timer expires, instructions in the operating system module 380 may return from the “sleep on event” subroutine, returning control to the orientation module 340.

The process 400 may then move to block 420, where the current device orientation is obtained from an orientation sensor. Block 420 may be implemented by instructions in orientation module 340 of FIG. 3 obtaining data from an orientation sensor 345. The process 400 may then move to decision block 430, where the orientation data read from the orientation sensor is evaluated to determine whether it indicates a first or second orientation. If the orientation data indicates a first orientation, the process 400 may move from decision block 430 to processing block 435, where one or more imaging sensors of a first orientation are selected. For example, in the implementation of device 200 shown in FIG. 2, processing block 435 may select imaging sensors 210a and 210b. If the orientation data from the orientation sensor indicates a second orientation, process 400 may move from decision block 430 to processing block 440, where one or more imaging sensors of a second orientation are selected. For example, in the implementation of device 200 shown in FIG. 2, processing block 440 may select imaging sensors 210a and 210c. The process 400 may then move to decision block 445, which evaluates whether process 400 should repeat. Process 400 may not repeat, for example, when a device running process 400 transitions from an image capture mode to a non-image capture mode, such as an image display mode. A power off event may also cause process 400 to not repeat. If conditions are such that process 400 should repeat, process 400 may return to processing block 410 and the process 400 may be repeated. Otherwise, the process 400 may move from decision block 445 and end.

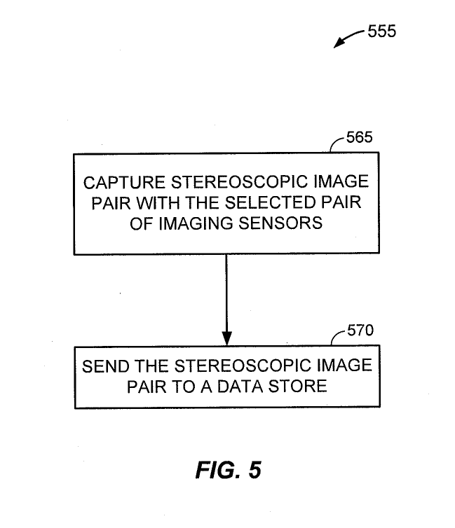

FIG. 5 is a flowchart of a process for capturing a stereoscopic image pair using a pair of selected imaging sensors. The process 555 of FIG. 5 may run asynchronously with the process 400. For example, the operating system module 380 of FIG. 3 may allocate one process to run process 400 and one process to run process 555. The process 400 may be performed by instructions in the sensor selection module 346 of FIG. 3. The process 555 may be performed by instructions included in the stereoscopic imaging module 370 of FIG. 3. The process 400 may perform continuous selection of an imaging sensor pair based on a device orientation. The process 555 of FIG. 5 may then capture a stereoscopic image pair at any time the process 400 is also running using the imaging sensor pair that is currently selected by the process 400. In processing block 565, a stereoscopic image pair (or a plurality of consecutive image pairs for stereographic video) is captured using the pair of imaging sensors selected by the process 400. The process 555 may then move to processing block 570 where the stereoscopic image pair is sent to and stored in a data store. Processing block 570 may be implemented by instructions included in the stereoscopic imaging module 370, illustrated in FIG. 3.

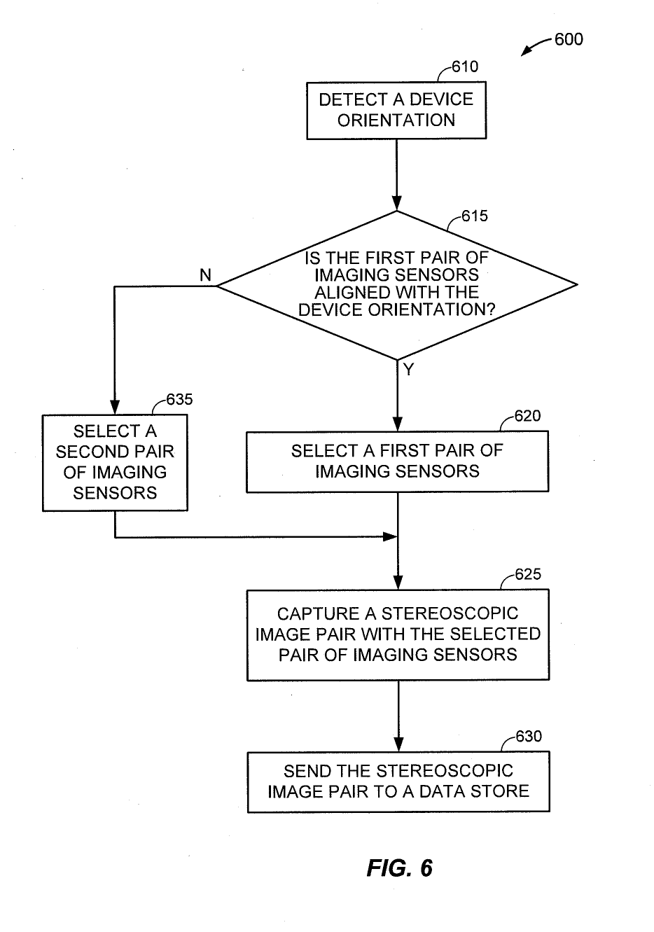

FIG. 6 shows a flowchart of a process for capturing a stereoscopic image pair based on a device orientation. In contrast with the processes shown in FIGS. 4 and 5, process 600 of FIG. 6 may be implemented by a single process. For example, the operating system module 380 of FIG. 3 may allocate a single process to perform the process 600. The process 600 may be implemented by a combination of instructions included in the stereoscopic imaging module 370, the sensor selection module 346, the orientation module 340, and the sensor control module 335 as illustrated in FIG. 3. In processing block 610, a device orientation is detected. Processing block 610 may be performed by instructions included in the orientation module 340 of FIG. 3. Therefore, instructions in an orientation module 340, along with orientation sensor 345 may represent one means for detecting a device orientation.

The process 600 may then move to decision block 615, where it is determined whether the detected orientation is aligned with a first pair of imaging sensors. In some implementations, the first pair of imaging sensors may be aligned when the device is in a horizontal orientation. For example, the first pair of imaging sensors may be, in some implementations, imaging sensors 110c and 110d, as illustrated in FIG. 1. In other implementations, the first pair of imaging sensors may be aligned when the device is in a portrait or vertical orientation. For example, in some implementations, the first pair of imaging sensors may be imaging sensors 110a and 110b, as illustrated in FIG. 1. If the first pair of imaging sensors in the process 600 is aligned with the device orientation, the process 600 may move from decision block 615 to processing block 620, where the first pair of imaging sensors is selected. If the first pair of imaging sensors is not aligned with the device orientation, the process 600 may move to block 635, where a second pair of imaging sensors is selected. Processing blocks 615, 620 and 635 may be implemented by instructions included in the sensor selection module 346 as illustrated in FIG. 3. Therefore, instructions in the sensor selection module may represent one means for selecting a pair of imaging sensors.

The process 600 may then move from either processing block 635 or processing block 620 to processing block 625, where a stereoscopic image pair is captured with the selected pair of imaging sensors. Processing block 625 may be implemented by instructions in the stereoscopic imaging module 370 as illustrated in FIG. 3. Instructions in stereoscopic imaging module 370 may call subroutines in, for example, the sensor control module 335 to capture the stereoscopic image. Therefore, instructions in the sensor control module 335 may represent one means for capturing a stereoscopic image pair.

The process 600 may then move to processing block 630, where the stereoscopic image pair captured in block 625 is sent to and written in a data store. Block 630 may be implemented by instructions in stereoscopic imaging module 370. Those instructions may write imaging data returned from two of imaging sensors 210a-c to the data store 310. Therefore, instructions in stereoscopic imaging module 370 may represent one means for writing a stereoscopic image pair to a data store.

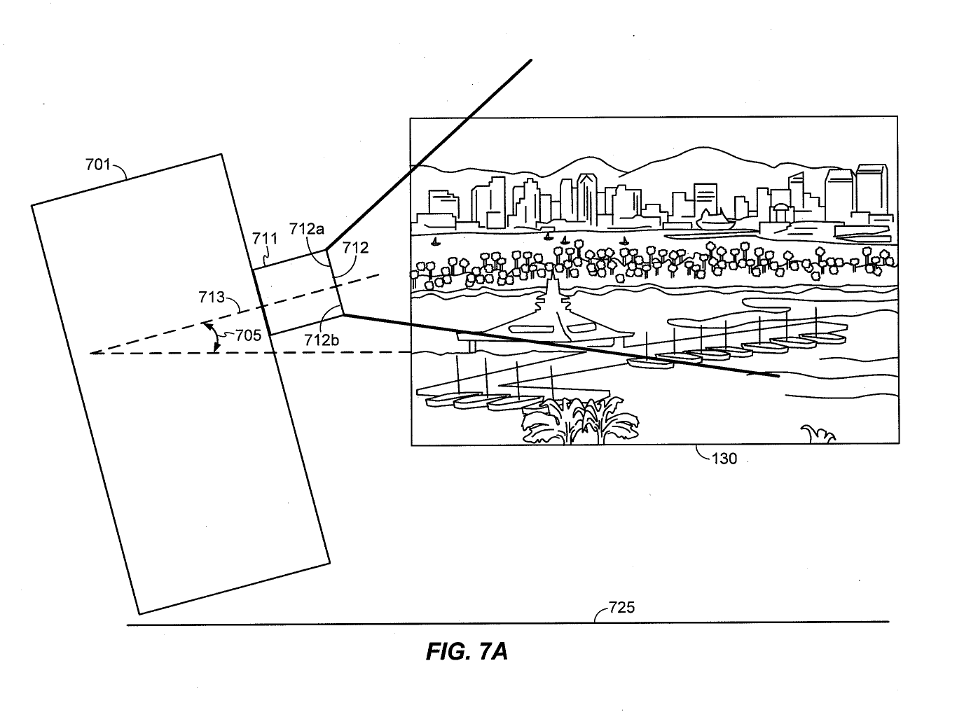

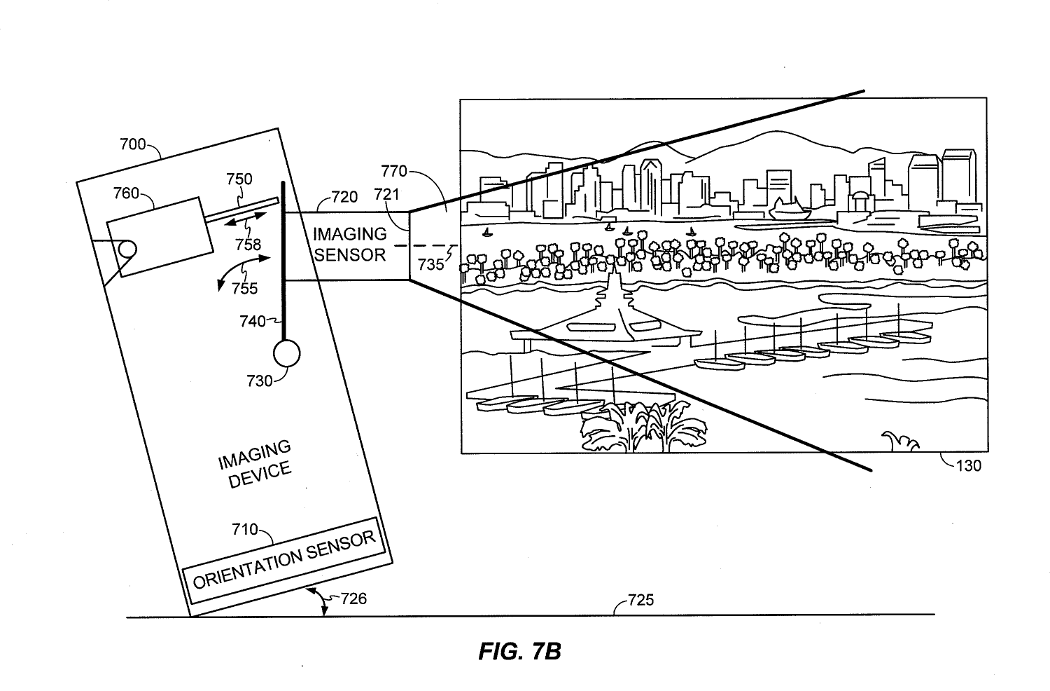

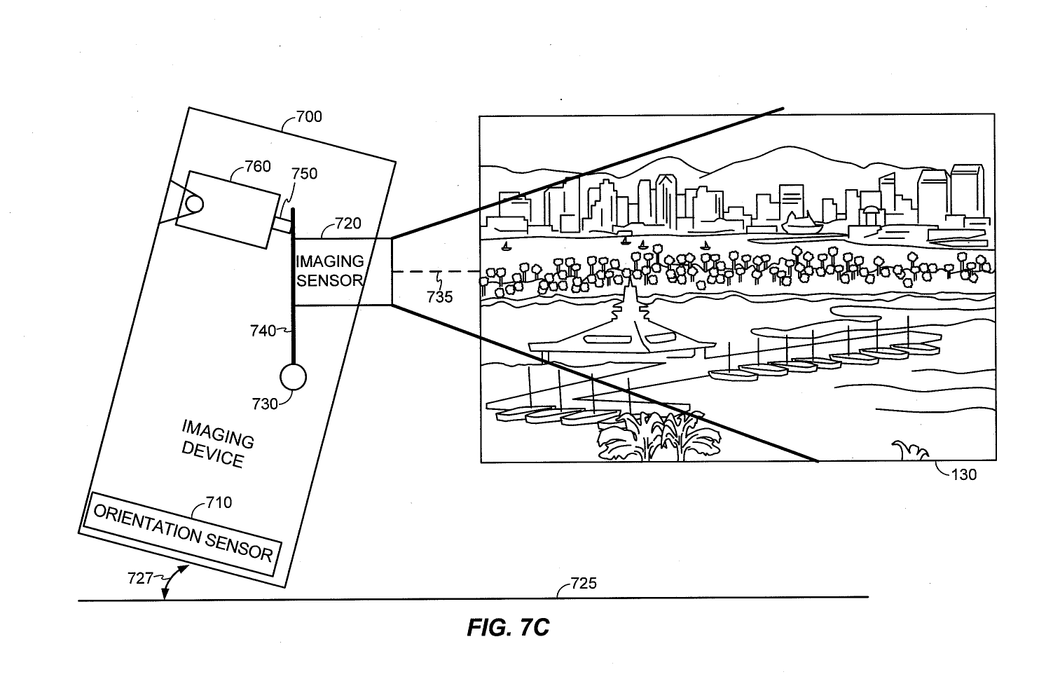

FIG. 7A illustrates an imaging device positioned at an angle or tilt relative to a scene being imaged. Imaging device 701 is shown imaging a scene 130. Imaging device 701 includes at least one imaging sensor 711. In traditional imaging devices with imaging sensors fixed in a rigid position with respect to a body or case of the imaging device such as device 701, tilting the device also tilts the imaging sensor used to capture the image. This may change the angle of the optical axis of the imaging sensor lens with respect to the scene being imaged, as can be observed in FIG. 7A. Tilt angle 705 shows that the tilt of device 701 has introduced an angle 705 between the optical axis 713 of the lens 712 of the imaging sensor 711 and the scene being imaged. An angle between the optical axis 713 and a scene captured by the imaging sensor may introduce level distortion into the image being captured. In FIG. 7A, the tilt produces a tilt angle 705 and causes the upper portion 712a of the imaging sensor lens 712 to be further from the scene than the lower portion 712b of the lens 712.

FIG. 7B illustrates an imaging device including an imaging sensor with an adjustable level control. Imaging device 700 is shown at a similar tilt angle with respect to the scene being imaged 130 as was shown in FIG. 7A with device 701. Imaging device 700 includes an orientation or tilt sensor 710. The orientation sensor 710 may be configured to detect a tilt angle with respect to a horizontal surface 725 such as the earth's surface. This angle is shown as tilt angle 726. Imaging device 700 may also include a mechanical or electronic lens leveling adjustment capability. The implementation of this capability may vary by implementation. One example of a mechanical implementation is shown in FIG. 7B. In the implementation of FIG. 7B, the capability is provided by a combination of mechanical components, including a hinge control motor 760, actuator rod 750, adjustable imaging sensor mount 740, and hinge 730. Hinge control motor may be a stepper motor, and be electronically controlled by processing circuitry or logic included in device 700. Hinge control motor 760 may move actuator rod 750 as shown by double arrow 758. This motion of actuator rod 750 may move adjustable imaging sensor mount 740 as shown by double arrow 755. When the position of imaging sensor 720 is adjusted by the lens leveling adjustment capability, the optical axis 735 of lens 721 of imaging sensor 720 may remain directed towards the scene being imaged with essentially a zero tilt angle, as shown by the parallelism of the optical axis 735 and the horizontal surface 725. Note that imaging device 700 may be one implementation of device 100 of FIG. 1 or device 200 of FIG. 2 or FIG. 3.

FIG. 7C illustrates the imaging device with an opposite tilt as compared to FIG. 7B. In FIG. 7C, actuator rod 750 is shown retracted further into hinge control motor 760 as compared to its position in FIG. 7B to accommodate a tilt angle 727 with respect to the horizontal surface 725. This has resulted in a repositioning of adjustable imaging sensor mount 740 so as to maintain the alignment of imaging sensor 720 with the scene 130 being imaged. This can be observed by the parallelism between the optical axis 735 of the image sensor 720 and the horizontal surface 725.

The mechanical and electronic tilt angle correction techniques described herein can be applied to the stereoscopic imaging sensors described above with respect to FIGS. 1-6. In one example of a use case, a cell phone or other wireless mobile device having a backside (opposite the display side) camera (not shown) may capture and transmit level-corrected 2-D or 3-D video images from the backside camera(s) to another mobile device, allowing users of each device to view the scene while holding the mobile device in an often-used and somewhat downward-pointing (negative tilt angle) position while walking or sitting. During a real-time video call, for example, one user may capture images of the scene in front of the phone and transmit the images to another user, while the first user holds the phone at a non-zero tilt angle to allow comfortable interactions with a touch panel on the phone's display or keyboard.

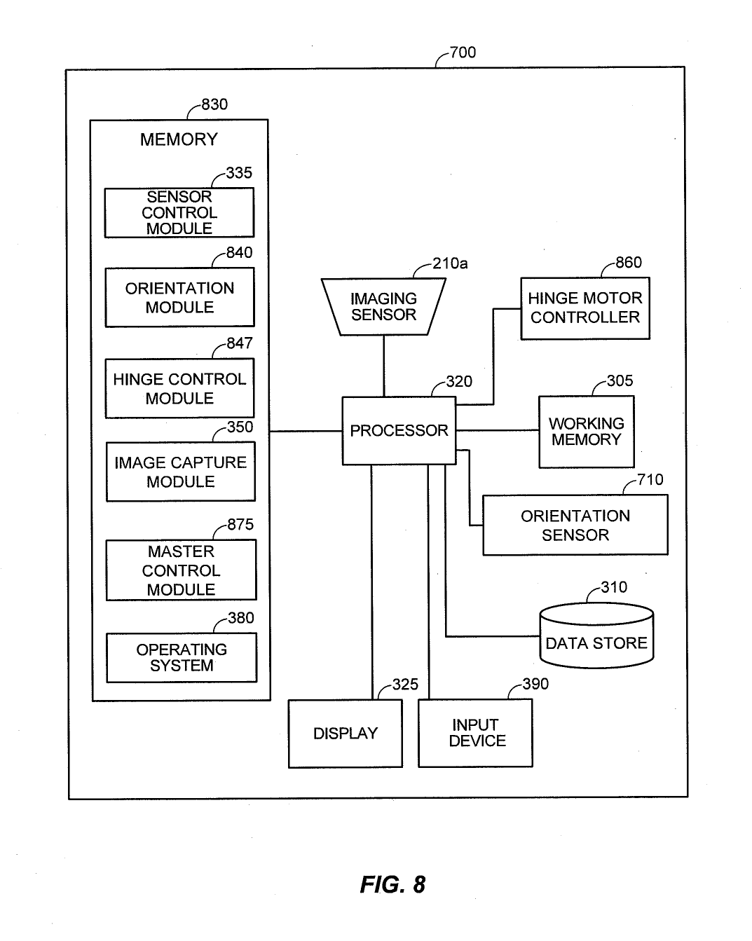

FIG. 8 is a block diagram of an imaging device implementing at least one of the methods and apparatuses disclosed herein. Imaging device 700 shares some similarities with imaging device 200 discussed with respect to FIG. 3. Imaging device 700 includes a processor 320. Operably connected to the processor 320 are a working memory 305, data store 310, input device 390, and display 325. Imaging device 700 also includes a hinge motor controller 860, a tilt or orientation sensor 710, and memory 830. Orientation sensor 710 may be configured to detect a tilt of the imaging device 700 with respect to a horizontal surface such as the surface of the earth. For example, the orientation sensor 710 may be configured as shown in FIGS. 7B and 7C. Note that although device 700 is illustrated with only one imaging sensor 210a, other implementations of device 700 may include multiple imaging sensors including one or more pairs of stereographic imaging sensors.

The memory 830 includes several modules that include processor instructions for processor 320. These instructions configure the processor to perform functions of device 700. As described earlier, sensor control module 335 includes instructions that configure processor 320 to control imaging sensor 210a. For example, processor 320 may capture images with imaging sensor 210a via instructions included in sensor control module 335.

Memory 830 also includes an orientation module 840. The orientation module 840 includes instructions that read device tilt information such as a tilt angle from orientation sensor 710. The hinge control module 847 may include instructions that configure processor 320 to control the position of a hinge or other mechanical positioning device included in device 800 (not shown). For example, the hinge control module 847 may send control signals to a hinge control motor, such as the hinge control motor 760 illustrated in FIGS. 7B and 7C via a hinge motor controller 860. The control signals may be sent to hinge control motor 760 by hinge motor controller 860. Instructions in hinge control module 847 may send higher level commands to hinge motor controller 860, which translates commands into electrical signals for hinge motor 760. This may move actuator rod 750 in the direction illustrated by arrow 758 of FIG. 7B or otherwise mechanically rotate or redirect the imaging sensor. This movement of the actuator rod 750 may position adjustable imaging sensor mount 740, as illustrated in FIGS. 7B and 7C.

The hinge control module 847 may also include instructions that read device tilt information from the orientation module 840, and adjust the position of actuator rod 750 to maintain a small tilt angle between the lens of the imaging sensor 210a and a scene being imaged. Effectively, this may be accomplished by maintaining parallelism between an optical axis of the imaging sensor 210a and a horizontal line or the surface of the earth.

The image capture module 350 may include instructions to capture photos or video, either stereoscopic or non-stereoscopic, with device 700. Its operation in imaging device 700 is substantially similar to its operation as described previously for the imaging device 200, illustrated in FIG. 3.

Instructions in the master control module 875 may control the overall device functions of device 700. For example, instructions in the master control module 875 may allocate a process within the operating system 380 to run the hinge control module 847. Instructions in the master control module 875 may also allocate a process from operating system 380 to run image capture module 350.

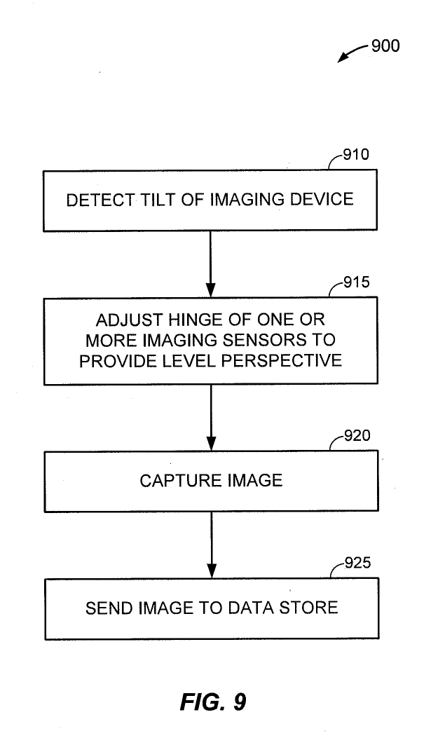

FIG. 9 is a flowchart of a process for detecting and compensating for the orientation or tilt of an imaging device before capturing one or more images. Process 900 may be implemented by instructions included in the hinge control module 847, the master control module 875, and orientation module 840, as illustrated in FIG. 8. In processing block 910, an orientation or tilt of the imaging device is detected. Block 910 may be implemented by instructions included in the orientation module 840 of FIG. 8. Alternatively, it may be implemented by instructions in the hinge control module 847, also of FIG. 8.

The process 900 then moves to processing block 915, where the hinge of one or more imaging sensors is adjusted to provide a level perspective. A level perspective in this context is one that places the optical axis of the lens of the imaging sensor parallel to a horizontal line, at a 90° angle to a line perpendicular to the local surface of the earth, or in the direction of another preferred orientation. Processing block 915 may be performed by instructions included in the hinge control module 847 of FIG. 8.

The process 900 then moves to block 920 where one or more images are captured. Block 920 may be performed by instructions included in the image capture module 350. Alternatively, instructions in the sensor control module 335 or the master control module 875 may perform block 920. The process 900 then moves to block 925, where the image may be sent to and/or saved in a data store. Block 925 may be performed by instructions included in the master control module 875 or the image capture module 350.

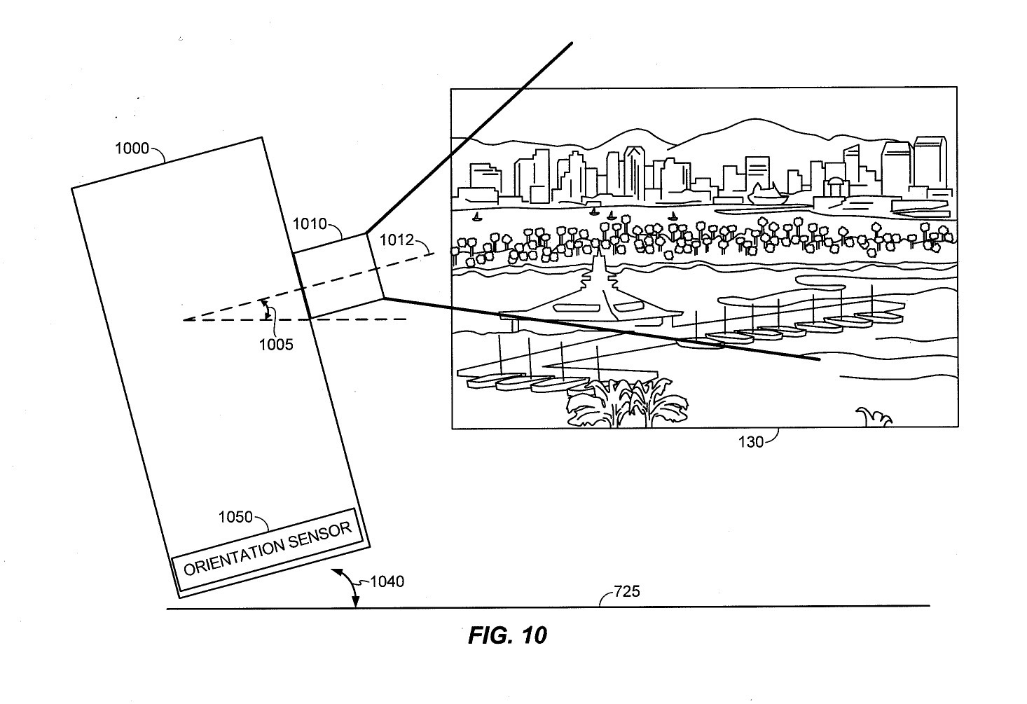

FIG. 10 shows an imaging device implementing at least one of the apparatus and methods disclosed herein. The imaging device 1000 includes an imaging sensor 1010 that is rigidly mounted to the case or frame of imaging device 1000. As such, when the imaging device 1000 is tilted at an angle 1040 with respect to the earth's surface 725 and a scene being imaged 130, an angle 1005 is introduced between an optical axis 1012 of the imaging sensor 1010 and the scene being imaged 130. Images captured with an uncorrected tilt angle 1005 may include level distortion. Note that imaging device 1000 may be one implementation of device 100 of FIG. 1. Imaging device 1000 may also represent an implementation of device 200 of FIG. 2 or FIG. 3.

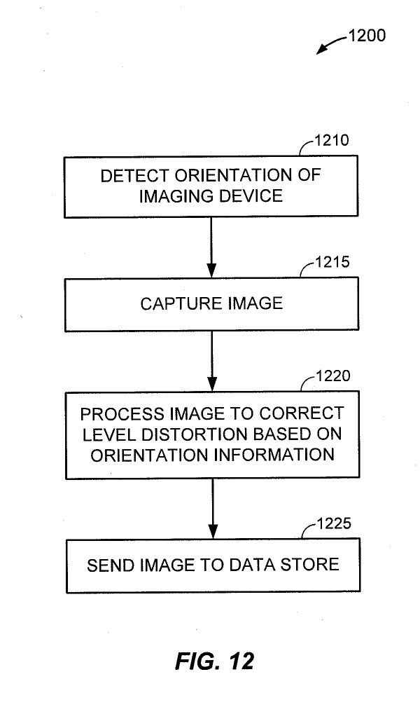

Imaging device 1000 may not include the ability to mechanically adjust the position of the imaging sensor 1010 relative to the body or frame of the imaging device 1000, as was shown with imaging device 700. Imaging device 1000 may include electronic processing capabilities to digitally adjust an image captured by imaging sensor 1010 based on input from an orientation or tilt sensor 1050. Electronic processing of images captured by device 1000 may reduce or eliminate level distortion caused by the tilt angle 1005 of imaging device 1000, as described below with respect to FIG. 12.

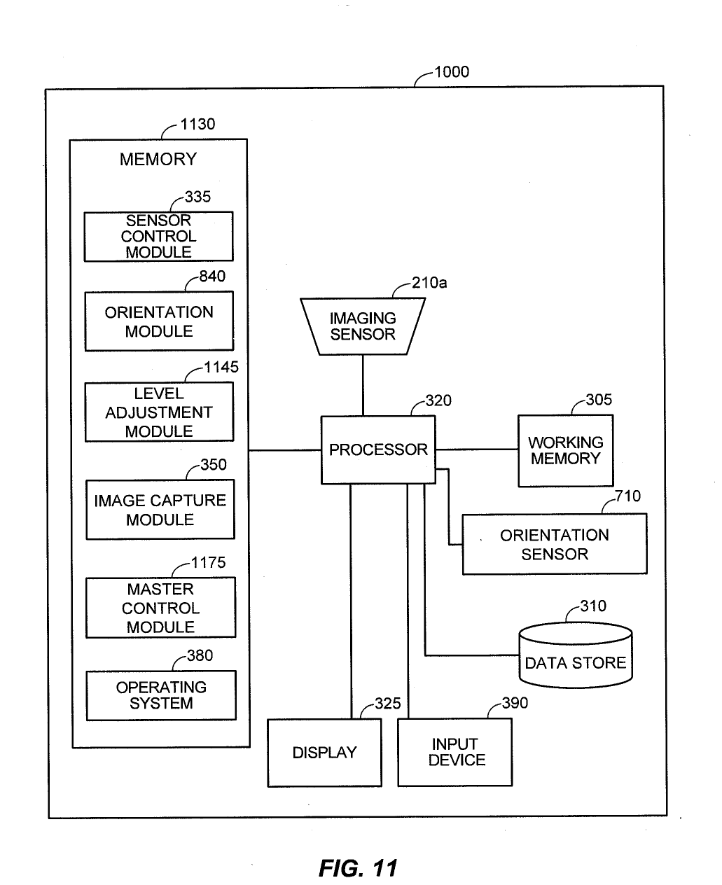

FIG. 11 is a block diagram of an imaging device implementing at least one of the methods and apparatus disclosed herein. The imaging device 1000 shares some similarities with the imaging device 200 as discussed with respect to FIG. 3, and some similarities with the imaging device 700, as discussed with respect to FIG. 8. The imaging device 1000 includes a processor 320. Connected to the processor 320 are at least one imaging sensor 210a, a working memory 305, a data store 310, an input device 390, and a display 325. The imaging device 1000 also includes a tilt or orientation sensor 710, and a memory 1130. The orientation sensor 710 may be configured to detect an orientation of the imaging device 1000 with respect to a horizontal line, the surface of the earth, or a scene being imaged. For example, the orientation sensor 710 may be configured as shown in FIGS. 7B and 7C. Note that although device 1000 is illustrated with only one imaging sensor, other implementations of device 1000 may include multiple imaging sensors including stereoscopic pairs of imaging sensors.

The memory 1130 includes several modules that include processor instructions for processor 320. These instructions may configure the processor to perform functions of device 1000. The sensor control module 335, the orientation module 840, the image capture module 350, and the operating system 380 perform similarly to the modules previously described.

Within the image device 1000 illustrated by FIG. 11 is a level adjustment module 1145. The level adjustment module 1145 includes instructions that configure processor 320 to digitally process images captured by the imaging sensor 210a. The level adjustment module may digitally process these images based on input from the orientation module 840. For example, level adjustment module 1145 may adjust images captured by imaging sensor 210a so as to reduce or eliminate level distortion caused by a tilt of device 1000 when the images were captured or by electronically selecting a portion of the image sensor 210a as the images are captured.

Instructions included in the master control module 1175 control overall device functions of device 1000. For example, instructions in the master control module 1175 may first detect an orientation of device 1000 by invoking subroutines in the orientation module 840. Instructions in the master control module 1175 may then capture an image by calling subroutines in the image capture module 350 and/or the sensor control module 335. Instructions in the master control module 1175 may then invoke subroutines in the level adjustment module 1145. As input, the level adjustment module subroutines may receive orientation information such as a tilt angle from the orientation module 840 or the orientation sensor 710, and digital image data produced by the imaging sensor 210a. Instructions in the level adjustment module 1145 may then adjust the image data to reduce level distortion caused by the tilt as detected by orientation sensor 710. Instructions in the master control module 1175 may then write or send this adjusted digital image data to the data store 310.

FIG. 12 shows a flowchart of a process for electronically adjusting a digital image to remove perspective or level distortion. The process 1200 may be implemented by instructions included in a combination of the master control module 1175, the image capture module 350, the level adjustment module 1145, and the orientation module 840, as illustrated in FIG. 11. In processing block 1210, an orientation of an imaging device is detected. For example, processing block 1210 may be implemented by instructions included in orientation module 840 as illustrated in FIG. 11. Process 1200 then moves to block 1215 where one or more images are captured. The images captured may be, for example, a digital image snapshot, a digital movie, a stereoscopic image, a stereoscopic video, or real-time streaming video for a video call. The image captured may also be one of several images used to form a single high dynamic range image. Processing block 1215 may be implemented by instructions included in the image capture module 350, illustrated in FIG. 11.

The process 1200 may then move to block 1220, where the image captured in block 1215 is processed to correct level distortion based on tilt information determined in block 1210. For example, electronic correction of image data for level distortion may involve electronically deleting image data above or below a desired viewing window. Alternatively, a viewing window may be electronically positioned in a desired direction or orientation, and the image data outside of the viewing window may be deleted. Alternatively, rows or groups of imaging pixels within the imaging sensor may be selectively addressed and others not addressed to achieve the desired orientation of the image data, based on the orientation or tilt information. Alternatively, image processing such as matrix manipulations may be performed on image data to compensate for tilt and orientation distortions. Image processing routines may be performed on image data from the imaging sensor to mask out data outside a desired viewing window and orientation, while optionally enlarging or otherwise enhancing image data within the viewing window to the desired aspect ratio and resolution. Processing block 1220 may be implemented by instructions included in the level adjustment module 1145, as illustrated in FIG. 11. The process 1200 may then move to processing block 1225, where the processed image may be sent to and saved in a data store. In some implementations, the processed image may be sent to a data store that is integrated with the imaging device. Alternatively, in some implementations, the processed image may be sent to a data store that is accessible over a wired or a wireless network. Block 1225 may be implemented by instructions included in the master control module 1175, as illustrated in FIG. 11.

The various illustrative logical blocks, modules, and circuits described in connection with the implementations disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or process described in connection with the implementations disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of non-transitory storage medium known in the art. An exemplary computer-readable storage medium is coupled to the processor such the processor can read information from, and write information to, the computer-readable storage medium. In the alternative, the storage medium may be integral to the processor. The processor and the storage medium may reside in an ASIC. The ASIC may reside in a user terminal, camera, or other device. In the alternative, the processor and the storage medium may reside as discrete components in a user terminal, camera, or other device.

The previous description of the disclosed implementations is provided to enable any person skilled in the art to make or use the present invention. Various modifications to these implementations will be readily apparent to those skilled in the art, and the generic principles defined herein may be applied to other implementations without departing from the spirit or scope of the invention. Thus, the present invention is not intended to be limited to the implementations shown herein but is to be accorded the widest scope consistent with the principles and novel features disclosed herein.

What is claimed is:

1. A stereoscopic imaging apparatus, comprising:
a first pair of imaging sensors aligned along a first axis with respect to the apparatus;
a second pair of imaging sensors aligned along a second axis with respect to the apparatus, wherein the second axis is substantially perpendicular to the first axis; and
a control module configured to capture stereoscopic images from the first pair of imaging sensors when the apparatus is in a first orientation and the second pair of imaging sensors when the apparatus is in a second orientation.

2. The apparatus of claim 1, wherein the first pair of imaging sensors and the second pair of imaging sensors share a common imaging sensor.

3. The apparatus of claim 1, further comprising an orientation sensor, wherein the control module selects the first pair or the second pair of imaging sensors based at least in part on an output from the orientation sensor.

4. The apparatus of claim 1, wherein the apparatus is a wireless telephone handset.

5. A method for capturing a stereoscopic image from a device having a first pair of imaging sensors and a second pair of imaging sensors, comprising:
detecting a device orientation;
selecting the first pair or the second pair of imaging sensors based on the device orientation;
capturing a stereoscopic image pair with the selected pair of imaging sensors; and
sending the stereoscopic image pair to a data store.

6. The method of claim 5, wherein the device orientation is detected by obtaining data from an orientation sensor associated with the device.

7. The method of claim 5, wherein the first pair of imaging sensors and the second pair of imaging sensors share one imaging sensor.

8. The method of claim 5, wherein the first pair of imaging sensors and the second pair of imaging sensors do not share an imaging sensor.

9. The method of claim 5, where in the device is a wireless telephone handset.

10. A stereoscopic imaging apparatus, comprising:
means for detecting a device orientation;
means for selecting a first pair of imaging sensors or a second pair of imaging sensors based on the device orientation;
means for capturing a stereoscopic image pair with the selected pair of imaging sensors; and
means for sending the stereoscopic image pair to a data store.

11. The stereoscopic imaging apparatus of claim 10, wherein the means for detecting a device orientation comprises an orientation sensor.

12. The stereoscopic imaging apparatus of claim 10, wherein the means for capturing a stereoscopic image pair includes processor instructions in a sensor control module.

13. The stereoscopic imaging apparatus of claim 10, wherein the means for selecting the first pair or the second pair of imaging sensors based on the device orientation includes processor instructions in a sensor selection module.

14. A non-transitory computer-readable medium comprising instructions that when executed by a processor perform a method of:
detecting a device orientation;
selecting a first pair of imaging sensors or a second pair of imaging sensors based on the device orientation;
capturing a stereoscopic image pair with the selected pair of imaging sensors; and
sending the stereoscopic image pair to a data store.

15. The computer-readable medium of claim 14, wherein the device orientation is detected by obtaining data from an orientation sensor coupled to the device.

16. A method for correcting level distortion in a digital image captured by a digital imaging device having a body and an imaging sensor, comprising:
measuring a tilt angle between the imaging sensor and a horizontal surface;
adjusting the tilt angle by changing electronically or mechanically the position of the imaging sensor within the body of the digital imaging device;
capturing an image with the imaging sensor; and
sending the image to a data store.

17. The method of claim 16, wherein measuring the tilt angle comprises obtaining tilt data from an orientation sensor coupled to the digital imaging device.

18. The method of claim 16, wherein measuring the angle between the imaging sensor and the horizontal surface comprises measuring the angle between a lens of the imaging sensor and the horizontal surface.

19. The method of claim 16, further comprising:
adjusting a tilt angle that a second imaging sensor makes with the horizontal surface by changing a position of the second imaging sensor, wherein the second imaging sensor is within the body of the digital imaging device.

20. The method of claim 16, wherein the method is performed in a wireless telephone handset.

21. A digital imaging device, comprising:
an imaging sensor;
an orientation sensor;
a processor, the processor operatively coupled to the imaging sensor and the orientation sensor;
an orientation module, the orientation module configured to read data from the orientation sensor and to determine a tilt angle between the imaging sensor and a horizontal surface;
an orientation control module configured to adjust the tilt angle by changing electronically or mechanically a position of the imaging sensor within the digital imaging device.

22. The device of claim 21, further comprising an image capture module configured to capture an image with the imaging sensor, and a master control module configured to send the image to a data store.

23. The digital imaging device of claim 21, further comprising an integrated data store, wherein a master control module is configured to send the image to the integrated data store.

24. The digital imaging device of claim 22, wherein the data store is accessible over a network.

25. The digital imaging device of claim 22, further comprising:
a second imaging sensor, wherein the orientation control module is further configured to adjust a tilt angle of the second imaging sensor by changing a position of the second imaging sensor within the digital imaging device.

26. The digital imaging device of claim 25, wherein the image capture module is further configured to capture a second image with the second imaging sensor.

27. A digital imaging device including a body and an imaging sensor, comprising:
means for measuring a tilt angle between the imaging sensor and a horizontal surface;
means for adjusting the tilt angle by changing electronically or mechanically the position of the imaging sensor within the body of the digital imaging device;
means for capturing an image with the imaging sensor; and
means for sending the image to a data store.

28. The digital imaging device of claim 27, further comprising means for capturing an image with a second imaging sensor.

29. The digital imaging device of claim 28, further comprising means for adjusting a tilt angle of the second imaging sensor with respect to the horizontal surface by changing electronically or mechanically the position of the second imaging sensor.

30. The digital imaging device of claim 27, wherein the data store is integrated with the digital imaging device.

31. A non-transitory computer readable medium, storing instructions that when executed by a processor cause the processor to perform the method of:
measuring a tilt angle between an imaging sensor and a horizontal surface;
adjusting the tilt angle by changing electronically or mechanically the position of an imaging sensor within a body of a digital imaging device;
capturing an image with the imaging sensor; and
sending the image to a data store.
